(19) United States
(12) Patent Application Publication
(10) Pub. No.: US 2023/0030617 A1
(43) Pub. Date: Feb. 2, 2023

(54) LEAK DETECTION CART AND LEAK DETECTION METHOD

(71) Applicant: CHANGXIN MEMORY TECHNOLOGIES, INC., Hefei City (CN)

(72) Inventor: Siyuan LI, Hefei City (CN)

(73) Assignee: CHANGXIN MEMORY TECHNOLOGIES, INC., Hefei City (CN)

(21) Appl. No.: 17/449,457

(22) Filed: Sep. 30, 2021

Related U.S. Application Data
(63) Continuation of application No. PCT/CN2021/110997, filed on Aug. 5, 2021.

(30) Foreign Application Priority Data
Jul. 29, 2021 (CN) 202110864554.6

(51) Int. Cl. G01M 3/04

(52) U.S. Cl. CPC G01M 3/04

(57) ABSTRACT

A leak detection cart at least includes a cart body and a fixing clip arranged on the cart body. The cart body is configured to place a component to be leak-detected, and the fixing clip is configured to fix the cart body and the component to be leak-detected. The cart body is provided with a leak detection hole, and the leak detection hole is located in a projection region of the component to be leak-detected on the cart body, and is configured to implement a leak detection for the component to be leak-detected.

### CROSS-REFERENCE TO RELATED APPLICATIONS

This is a continuation of International Patent Application No. PCT/CN2021/110997 filed on Aug. 5, 2021, which claims priority to Chinese Patent Application No. 202110864554.6 filed on Jul. 29, 2021. The disclosures of these applications are hereby incorporated by reference in their entirety.

### BACKGROUND

During Preventive Maintenance (PM) of a chamber, a film deposition machine will replace a dome at the top of the chamber and a reaction gas top injector connected to the dome at the top of the chamber, and the unloaded dome and top injector are cleaned for next use.

### SUMMARY

Embodiments of this disclosure relate to, but are not limited to, a leak- detecting cart and a leak detection method.

According to a first aspect of this disclosure, there is provided a leak detection cart. The leak detection cart at least includes a cart body and a fixing clip arranged on the cart body. Herein, the cart body is configured to place a component to be leak-detected, the fixing clip is configured to fix the cart body and the component to be leak-detected. The cart body is provided with a leak detection hole, and the leak detection hole is located in a projection region of the component to be leak-detected on the cart body, and is configured to implement a leak detection for the component to be leak-detected.

According to a second aspect of this disclosure, there is provided a leak detection method at least applied to the above leak detection cart. The method includes: a component to be leak-detected is subjected to a pre-leak-detection by the leak detection cart, and when a result of the pre-leak-detection meets a requirement, the component to be leak-detected is subjected to a further leak detection on a specific machine.

### BRIEF DESCRIPTION OF THE DRAWINGS

In the figures not necessarily drawn to the scale, a similar reference numeral may describe a similar element in different figures. A similar reference numeral with different suffix letters may illustrate different examples of a similar element. The figures generally illustrate various embodiments discussed herein in an example manner rather than a limitation manner.

FIG. 1 is an optional structure schematic diagram of a leak detection cart according to embodiments of this disclosure.

FIG. 2A is an optional structure schematic diagram of a leak detection cart according to embodiments of this disclosure.

FIG. 2B is a top view of a leak detection cart according to embodiments of this disclosure.

FIG. 2C is a bottom view of a leak detection cart according to embodiments of this disclosure.

FIG. 2D is a structure schematic diagram of a connecting support according to embodiments of this disclosure.

FIG. 3 is an optional schematic flowchart of a leak detection method according to embodiments of this disclosure.

FIG. 4A is a first structure schematic diagram of a chamber dome according to embodiments of this disclosure.

FIG. 4B is a second structure schematic diagram of a chamber dome according to embodiments of this disclosure.

FIG. 4C is a first structure schematic diagram of a top injector according to embodiments of this disclosure.

FIG. 4D is a second structure schematic diagram of a top injector according to embodiments of this disclosure.

FIG. 4E is a schematic diagram of a combined structure of a chamber dome and a top injector according to embodiments of this disclosure.

FIG. 4F is a first structure schematic diagram illustrating that a combined structure of a chamber dome and a top injector is fixed on a leak detection cart according to embodiments of this disclosure.

FIG. 4G is a second structure schematic diagram illustrating that a combined structure of a chamber dome and a top injector is fixed on a leak detection cart according to embodiments of this disclosure.

FIG. 4H is a structure schematic diagram illustrating that a helium test is performed on a combined structure of a chamber dome and a top injector by a leak detection cart according to embodiments of this disclosure.

### DETAILED DESCRIPTION

The exemplary implementation modes of this disclosure will be described in more detail below with reference to the accompanying drawings. Although the drawings show exemplary implementation modes of this disclosure, it should be understood that this disclosure can be implemented in various forms and shall not be limited by implementation modes described herein. On the contrary, these implementation modes are provided for a more thorough understanding of this disclosure, and for being able to fully convey the scope of the disclosure to those skilled in the art.

A number of specific details are given below to provide a more thorough understanding of this disclosure. However, it is apparent to those skilled in the art that this disclosure can be implemented without one or more of these details. In other examples, in order to avoid confusion with this disclosure, some technical features known in the art are not described; namely, not all the features of the actual embodiments are described here, and the known functions and structures are not described in detail.

In the drawings, dimensions of layers, regions and elements and their relative dimensions may be exaggerated for clarity. The same reference numerals throughout represent the same elements.

It is to be understood that the expression that an element or layer is positioned “above”, “adjacent to”, “connected to”, or “coupled to” another element or layer may refer to that the element or layer is positioned directly above, adjacent to, connected to or coupled to the other element or layer, or there may be an intermediate element or layer. On the contrary, the expression that an element is positioned “directly on”, “directly adjacent to”, “directly connected to” or “directly coupled to” another element or layer refers to that there is no intermediate element or layer. It is to be understood that, although various elements, parts, regions, layers and/or portions may be described with terms “first”, “second”, “third”, etc., these elements, parts, regions, layers and/or portions should not be limited to these terms. These terms are used only to distinguish one element, part, region, layer or portion from another element, part, region, layer or portion. Therefore, a first element, part, region, layer or portion discussed below may be represented as a second element, part, region, layer or portion without departing from the teaching of this disclosure. In addition, when a second element, part, region, layer or portion is discussed, it does not necessarily imply the existence of a first element, part, region, layer or portion of this disclosure.

The terms used herein are for the purpose of describing specific embodiments only and not intended to limit the disclosure. As used herein, singular forms “a”, “an”, and “the/said” are also intended to include the plural forms, unless otherwise specified in the context. It is also to be understood that, when terms “composed of” and/or “include” are used in this specification, the presence of the features, integers, steps, operations, elements, and/or parts is determined, but the presence or addition of one or more other features, integers, steps, operations, elements, parts, and/or groups is not excluded. As used herein, term “and/or” includes any and all combinations of the related listed items.

Both the dome and the top injector are brittle ceramic materials, so scratches easily are generated on the surfaces of the dome and the top injector during the cleaning process. The scratches will affect the engagement reliability of an engaging surface between the dome and the top injector, and then the chamber leaking rate of the film deposition machine is increased. Therefore, it may not be impossible to pass the helium leaking test, and thus the dome and the top injector need to be reinstalled. Each reinstallation will consume most of time in the PM and delay the simultaneous proceeding of other PM items, thereby increasing the material cost and time cost.

Typically, the dome and the top injector are engaged by an O-ring. After the dome and the top injector are operated for a period of time in a vacuum environment and a higher production process temperature, the dome and the top injector are tightly engaged. Moreover, since the dome and the top injector belong to the ceramic materials, the dome and the top injector are easily consumable parts.

A practice for maintaining the film deposition machine is that the dome and the top injector unloaded from the machine are delivered to a designated cleaning manufacturer for cleaning, and the cleaning manufacturer will adopt sand blasting, acid soaking and other processes to achieve the requirements of surface cleaning and surface roughness of the dome and the top injector. The dome and the top injector each are ceramic material and have curved surface in shape, so scratches or ceramic cracking are easily generated during the sand blasting due to the brittle ceramic material, and the scratches or ceramic cracking will affect the engagement reliability of the engaging surface of the dome and the top injector. Moreover, multiple reuses of parts may result in the problem of the part life, so that the chamber leaking rate of the machine is increased, and thus the helium leaking test cannot be passed. However, there are many factors affecting the chamber leaking rate of the machine in the related art. Therefore, when the helium leaking test is not passed, it is needed to reinstall the dome and top injector or to replace new dome and top injector for re-installation and further leak-detection. Each re-installation will consume most of time in the PM and also delay the progress of other PM items, thereby increasing the material cost and time cost.

Based on the abovementioned problems, embodiments of this disclosure provide a leak detection cart and a leak detection method, which may perform a leak detection on a component to be leak-detected outside a machine, so as to save the time cost and the human cost.

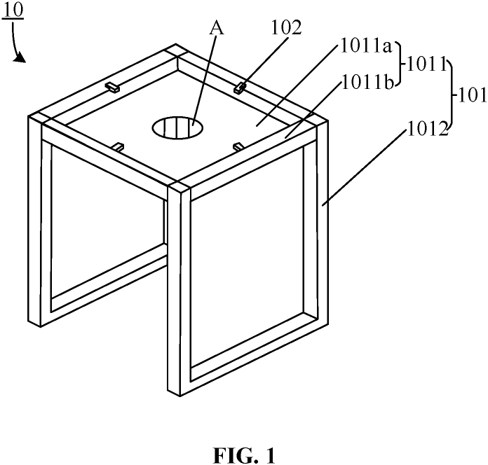

FIG. 1 is an optional structure schematic diagram of a leak detection cart according to embodiments of this disclosure. As shown in FIG. 1, the leak detection cart 10 includes a cart body 101 and a fixing clip 102 arranged on the cart body.

The cart body 101 is configured to place a component to be leak-detected (not shown in the figure). The fixing clip 102 is configured to fix the cart body 101 and the component to be leak-detected. The cart body has a leak detection hole A. The leak detection hole A is located in a projection region of the component to be leak-detected on the cart body 101, and the leak detection hole A is configured to implement a leak detection for the component to be leak-detected.

Herein, the leak detection hole may be located at any position in the projection region of the component to be leak-detected on the cart body, for example, located at the center of the projection region or the edge of the projection region. The leak detection hole may be a circular hole, an elliptic hole, a triangular hole, a rectangular hole or a polygonal hole. The leak detection hole is connected to an external leak detector through a leak detection pipeline, and then the component to be leak-detected is subjected to a leak detection by a leak detector. In embodiments of this disclosure, the leak detection hole may be a NW25 flange interface.

In embodiments of this disclosure, the cart body 101 includes a box body 1011 and a connecting support 1012. An end of the connecting support 1012 is fixedly connected to the box body 1011, and the connecting support 1012 is configured to support the box body 1011. Herein, the box body 1011 is provided with a base plate 1011a and at least one side plate 1011b connected to the base plate 1011a. The box body 1011 is configured to place the component to be leak-detected, the component to be leak-detected is located on a surface of the base plate 1011a of the box body 1011, the leak detection hole A is located in the base plate 1011a, and the fixing clip 102 is located on at least one side plate 1011b. The fixing clip 102 herein may be a snap-in clip, an elastic clip or other types of clips.

In embodiments of this disclosure, the box body is an opened container, which is configured to contain the component to be leak-detected. The box body is provided with four side plates, two adjacent side plates are connected to each other, and each side plate is connected to the base plate. In other embodiments, the box body may be also provided with one side plate, three side plates or five side plates.

In some embodiments, the connecting support may be movably connected to the box body.

In embodiments of this disclosure, the component to be leak-detected at least includes a first component and a second component, and the first component and the second component are fixed together to form the component to be leak-detected. The first component and the second component may be respectively two separate parts on a specific machine. The specific machine may be, for example, a film deposition machine, an etching machine or an encapsulating machine. In some embodiments, when the specific machine is the film deposition machine, the first component may be a chamber dome, and the second component may be a top injector.

The leak detection cart provided by embodiments of this disclosure may perform a leak detection on the component to be leak-detected outside the machine, so as to save the time cost and the human cost.

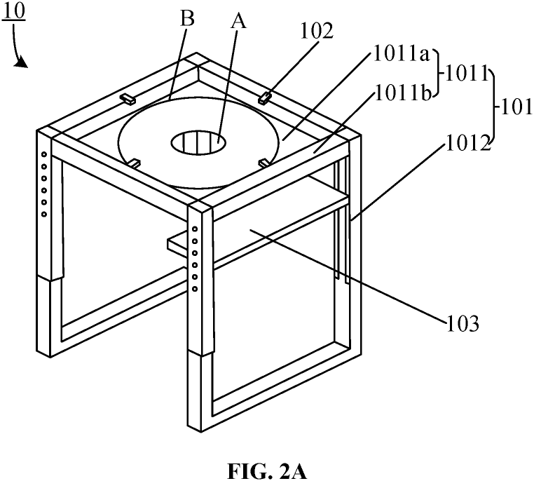

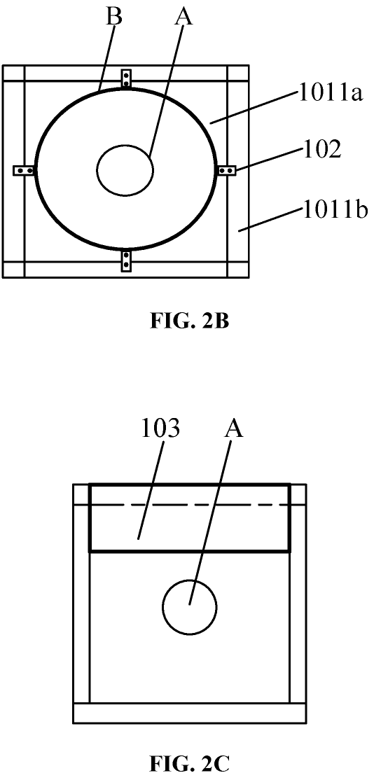

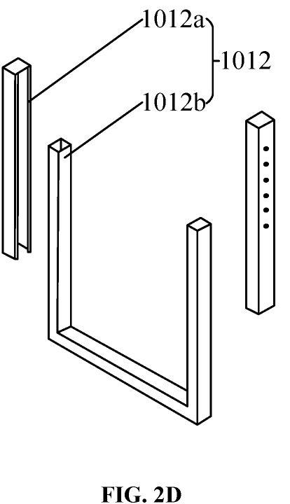

FIG. 2A is an optional structure schematic diagram of a leak detection cart according to embodiments of this disclosure. The leak detection cart 10 includes a cart body 101, a fixing clip 102 arranged on the cart body, a brake universal wheel (not shown in the figure) and a supporting platform 103.

Herein, the cart body 101 is configured to place the component to be leak-detected. The fixing clip 102 is configured to fix the cart body 101 and the component to be leak-detected. The cart body 101 is provided with a leak detection hole A, the leak detection hole A is located in a projection region of the component to be leak-detected on the cart body 101, and the leak detection hole A is configured to implement the leak detection for the component to be leak-detected.

In some embodiments, the cart body 101 includes a box body 1011 and a connecting support 1012. An end of the connecting support 1012 is fixedly or movably connected to the box body 1011, and another end of the connecting support 1012 is rotatably connected to the brake universal wheel. The box body 1011 is configured to place the component to be leak-detected, the connecting support 1012 is configured to support the box body 1011, and the leak detection cart 10 can freely move by the brake universal wheel.

The leak detection cart provided by embodiments of this disclosure may freely move by the brake universal wheel, and stop at any suitable place, for convenient use.

In embodiments of this disclosure, the leak detection cart includes four brake universal wheels. In other embodiments, the leak detection cart may also include two fixed casters and two brake universal wheels. The two fixed casters are driven by the two brake universal wheels, so that the leak detection cart may freely move.

In some embodiments, the box body 1011 is provided with a base plate 1011a and at least one side plate 1011b connected to the base plate. FIG. 2B and FIG. 2C are a top view and a bottom view of a leak detection cart respectively. As shown in FIG. 2A-FIG. 2C, it can be seen that the leak detection hole A is located at the center of the base plate 1011a, and the fixing clip 102 is located on at least one side plate 1011b. The base plate 1011a is further provided with a groove B, and the groove B is located in a contact position of the base plate 1011a with the component to be leak-detected.

In embodiments of this disclosure, the groove B is configured to place a sealing element, so that a sealing between the base plate and the component to be leak-detected is implemented by the sealing element. The groove B may be a circular groove, an elliptic groove, a triangular groove, a rectangular groove or a polygonal groove. The sealing element may be a sealing ring or a sealing strip, for example, an O-ring.

In embodiments of this disclosure, the sealing element is arranged between the component to be leak-detected and the leak detection cart (namely, in the groove), so that the engaging surface of the component to be leak-detected may be prevented from being damaged.

In embodiments of this disclosure, the supporting platform is a platform with a specific thickness. Still referring to FIG. 2A and FIG. 2C, the supporting platform 103 is located in a projection region of the base plate 1011a, and an area of the supporting platform 103 is less than or equal to that of the base plate 1011a. In embodiments of this disclosure, the leak detection hole A is connected to the external leak detector through the leak detection pipeline, and then the component to be leak-detected is subjected to leak detection by the leak detector. The supporting platform 103 is configured to increase the hand stability of an engineer when installing the leak detection pipeline.

FIG. 2D is a structure schematic diagram of a connecting support according to embodiments of this disclosure. As shown in FIG. 2D, the connecting support 1012 includes a connecting rod 1012a and an adjusting leg frame 1012b, the connecting rod 1012a is engaged with the adjusting leg frame 1012b, and the connecting rod 1012a and the adjusting leg frame 1012b can move relative to each other. The connecting rod 1012a and the adjusting leg frame 1012b are configured to adjust the height of the leak-detecting cart together.

In some embodiments, the adjusting leg frame may be snap-fitted into the connecting rod. A plurality of protrusions are provided on the adjusting leg frame, and a plurality of notches are provided in the corresponding connecting rod. Or, a plurality of notches are provided in the adjusting leg frame, and a plurality of protrusions are provided on the corresponding connecting rod. The notches and the protrusions are configured to adjust the relative position of the connecting rod to the adjusting leg frame together.

In some embodiments, the supporting platform 103 is fixedly or slidably connected to the adjusting leg frame 1012b, and the adjusting leg frame 1012b is also configured to adjust the height of the supporting platform 103.

According to the leak detection cart provided by embodiments of this disclosure, the connecting support for supporting the box body may be composed of two parts that can move relative to each other, and the supporting platform may move relative to the connecting support, so that the height of the leak detection cart and the height of the supporting platform in the leak detection cart may be adjusted according to demands for convenient use.

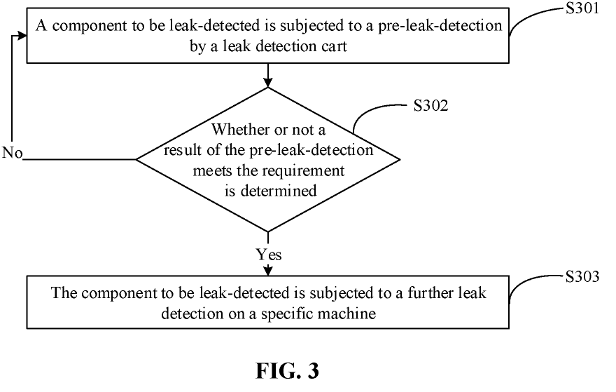

In addition, embodiments of this disclosure further provide a leak detection method, at least applied to the leak detection cart in the above embodiments. FIG. 3 is an optional schematic flowchart of a leak detection method according to embodiments of this disclosure. As shown in FIG. 3, the method includes the following steps.

At S301, the component to be leak-detected is subjected to a pre-leak-detection by the leak detection cart.

In embodiments of this disclosure, the leak detection cart at least includes a car body and a fixing clip arranged on the cart body. The cart body at least includes a box body at least provided with a base plate, and the base plate is provided with a leak detection hole and a groove. S301 may include the following steps.

A sealing element is placed in the groove.

The sealing element may be a sealing ring or a sealing strip.

The component to be leak-detected is hermetically fixed on the leak detection cart by the sealing element and the fixing clip.

The sealing element is located at a contact position of the component to be leak-detected with the base plate of the box body, and the component to be leak-detected is fixed to the leak detection cart by the sealing element and the fixed clip on the cart body.

The leak detection hole, a vacuum pump and a leak detector are connected by a leak detection pipeline.

In embodiments of this disclosure, an end of the leak detection pipeline is connected to the leak detection hole through a flange, and another end of the leak detection pipeline is connected to the vacuum pump and the leak detector respectively.

The component to be leak-detected is subjected to pre-leak-detection by the vacuum pump and the leak detector.

In some embodiments, the operation that the component to be leak-detected is subjected to pre-leak-detection by the vacuum pump and the leak detector includes the following operation.

A sealed space between the component to be leak-detected and the leak detection cart is vacuumized by the vacuum pump.

Herein, the vacuum pump may be a gas capturing pump or a gas transfer pump.

A specific type of gas is sprayed outside the component to be leak-detected, and the leak detector can detect the specific type of gas.

In embodiments of this disclosure, the specific type of gas may be helium, neon, argon, krypton or xenon. Correspondingly, the leak detector may be a helium detector, an argon detector, a krypton detector or a xenon detector.

The sealed space is subjected to continuous gas extracting treatment through the leak detector, so as to implement pre-leak-detection on the component to be leak-detected.

Since the space between the component to be leak-detected and the cart body is completely sealed, by spraying the specific type of gas around the component to be leak-detected, and detecting whether or not the specific type of gas exists in the component to be leak-detected by the leak detector, the leak detection on the component to be leak-detected may be implemented.

In embodiments of this disclosure, the component to be leak-detected at least includes a first component and a second component, and the first component and the second component are two separate parts on the specific machine.

In some embodiments, before the component to be leak-detected is hermetically fixed on the leak detection cart, the method further includes the following operation. The first component and the second component are fixedly combined to form a fixedly combined structure.

At S302, whether or not a result of the pre-leak-detection meets the requirement is determined.

In a case that the leak detector detects the specific type of gas, it indicates that the result of the pre-leak-detection does not meet the requirement, and in a case that the leak detector does not detect the specific type of gas, it indicates that the result of the pre-leak-detection meets the requirement. In embodiments of this disclosure, when the result of the pre-leak-detection meets the requirement, S303 is executed, and when the result of the pre-leak-detection does not meet the requirement, the method returns to S301 and S301 is executed.

In embodiments of this disclosure, when the result the pre-leak-detection does not meet the requirement, it indicates that the gas tightness inside the component to be detected is poor. At this time, a new component to be detected needs to be replaced, and then the pre-leak-detection is performed again until the result of the pre-leak-detection meets the requirement.

At S303, the component to be leak-detected is subjected to a further leak detection on the specific machine.

In some embodiments, S303 includes the following steps.

The fixedly combined structure subjected to the pre-leak-detection is disassembled.

The disassembled fixedly combined structure is installed on the specific machine.

The fixedly combined structure is subjected to the further leak detection on the specific machine by the leak detector.

In embodiments of this disclosure, after the pre-leak-detection is performed on the fixedly combined structure of the first component and the second component on the leak detection cart, it indicates that the gas tightness in the component to be leak-detected is good. In this case, the complete fixedly combined structure is installed on the specific machine to perform a further leak detection. If the result of the further leak detection does not meet the requirement, it only indicates that the engagement between the component to be leak-detected and the specific machine is not tight, and thus a gas leaking point may be quickly determined and be accurately dealt with without affecting the production capacity of the machine.

In embodiments of this disclosure, if leakage is directly detected on the specific machine, the machine will be occupied, and thus the production capacity will be affected. Assembly and leak detection are firstly performed outside the machine, the machine may thus normally perform the production. Moreover, the leak detection is performed on the machine after the detection is completed outside the machine so that the leak detecting test can be quickly completed, and then the time is saved.

Taking the specific machine being the film deposition machine, the component to be leak-detected including the dome and the top injector and the leak detection process being a helium leak detection process as an example below, the leak detection method provided by the embodiments of this disclosure is introduced in detail.

Firstly, the dome and the top injector are combined outside, the combined dome and top injector are placed on a helium detection tool cart (corresponding to the leak detection cart in the above embodiments), to be stably placed, and then are fastened through a pressure fixing sheet (corresponding to the fixing clip in the above embodiments), a helium detector is connected to a bottom flange of a helium detection cart, and the helium detector is started for helium detection (corresponding to the pre-leak-detection process in the above embodiments). Secondly, after the helium detecting result is qualified, a further helium detection (corresponding to the further leak detection process in the above embodiments) is performed on the film deposition machine.

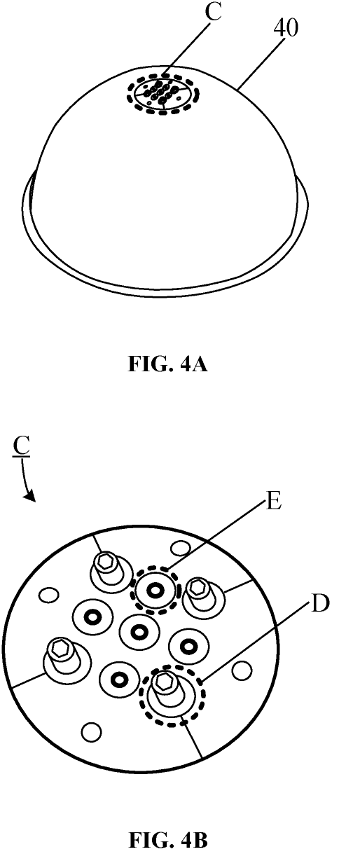

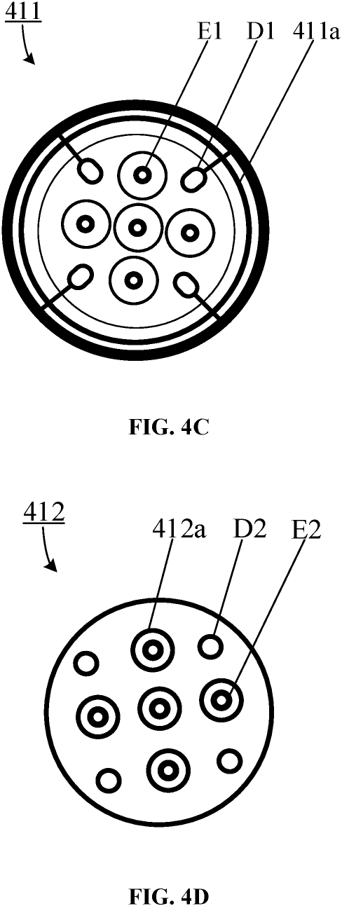

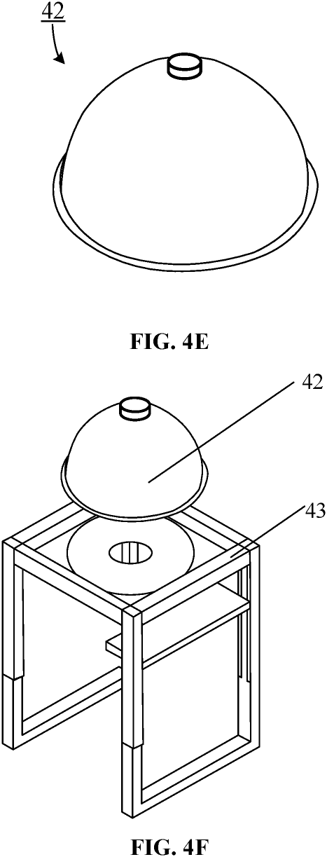

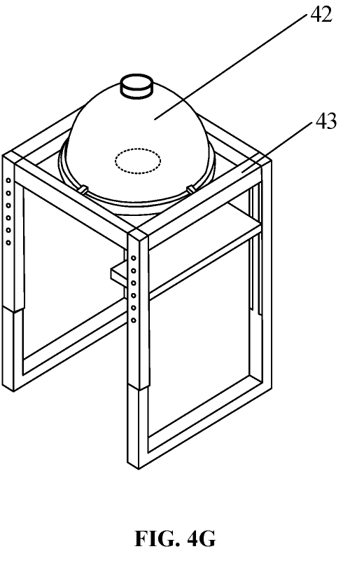

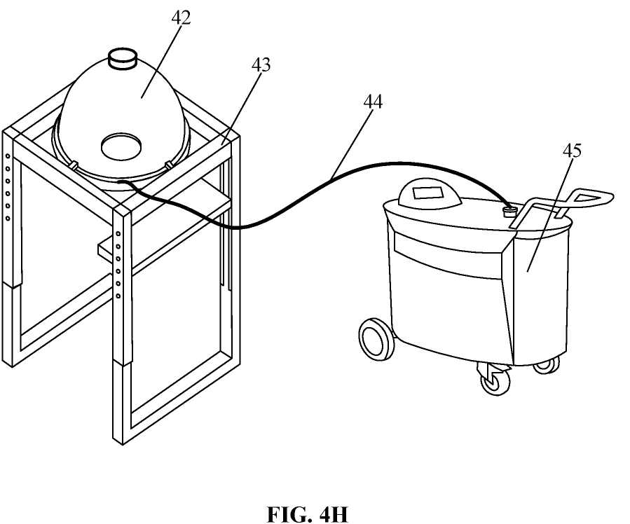

As shown in FIG. 4A and FIG. 4B, the place, where the chamber dome 40 is combined with the top injector, in the film deposition machine is a leak-prone helium detection region C, and the surface of the chamber dome 40 includes four fastening screw holes D and five gas transfer pipeline orifices E. As shown in FIG. 4C and FIG. 4D, in embodiments of this disclosure, the top injector includes two parts, one part is the top injector cover 411, and the other part is the top injector main body 412. Herein, the top injector cover 411 and the top injector main body 412 are also respectively provided with four fastening screws holes D1, D2 and five gas transfer pipeline orifices E1 and E2. In embodiments of this disclosure, the leak-prone helium detection region C on the film deposition machine may generate gas leak in three points: the first is the gas leak at the sealing ring of the top injector cover, the second is the gas leak at the sealing ring between the top injector cover and the top injector main body, and the third is the gas leak when the chamber dome and the top injector are matchingly assembly.

In embodiments of this disclosure, the process of external assembly of the chamber dome 40 and the top injector is as follows. Firstly, the top injector main body 412 is placed on the surface of the chamber dome 40, then the top injector cover 411 is covered on the surface of the top injector main body 412, and finally the top injector cover 411, the top injector main body 412 and the chamber dome 40 are fixed by adopting four fastening screws to form the combined structure 42 as shown in FIG. 4E. Herein, the top injector cover 411 and the top injector main body 412 are sealed through one large O-ring 411a and five small O-rings 412a.

As shown in FIG. 4F and FIG. 4G, the combined structure 42 of the chamber dome and the top injector is fixed on the leak detection cart 43, so that the combined structure 42 of the chamber dome and the top injector is subjected to pre-leak-detection by the leak detection cart 43. As shown in FIG. 4H, in embodiments of this disclosure, the leak detection cart 43 is connected to the external helium detector 45 through the leak detection pipeline 44, and the combined structure 42 of the chamber dome and the top injector is subjected to pre-leak-detection by the helium detector 45.

Still referring to FIG. 4H, in some embodiments, the process that the combined structure 42 of the chamber dome and the top injector is subjected to pre-leak-detection by the leak detection cart 43 is as follows. First, the space in the chamber dome and the top injector are vacuumized; the helium then is sprayed around (namely, the periphery of the combined structure 42) the chamber dome and the top injector; and finally, the helium detector 45 is used to extract gas all the time for testing. If a value of the helium detector 45 rises, it will give an alarm (since the helium detector is sensitive to the helium test, if the chamber dome and top injector are not well sealed, the helium sprayed from outside will certainly enter the chamber dome and top injector through a gap and be detected by the helium detector); and if the helium detector 45 does not give an alarm, it is considered that the airtightness between the chamber dome and top injector is good.

In a case that the airtightness between the chamber dome and the top injector is detected to be good by the helium detector, the combined structure of the chamber dome and the top injector is removed together and then is installed on the film deposition machine, to put it into use after the further helium test is performed.

The leak detection method provided by embodiments of this disclosure is at least applied to a helium detection cart in the abovementioned embodiments. For the technical features which are not disclosed in detail in the embodiments of this disclosure, please refer to the abovementioned embodiments for understanding and details are not made herein.

According to the leak detection method provided by embodiments of this disclosure, the dome and the top injector are assembled outside the machine, and a movable external leak detection cart is used, to achieve the advantages of convenient movement, time saving and accurate helium detection. Furthermore, the engaging surface of the combined structure of the dome and the top injector will not be scratched, to achieve the advantages of rapid leak detection, rapid separation and rapid clarification.

In the embodiments of the disclosure, it is to be understood that the disclosed device and method may be implemented through a non-target manner. The embodiment of the device described above is merely an example. For example, the unit division is merely logical function division and may be other division in actual implementation. For example, a plurality of units or components may be combined or integrated into another system, or some features may be ignored or not performed. In addition, components shown or discussed are coupled to each other, or directly coupled.

The several methods provided by the disclosure or features disclosed in the embodiments of the device may be arbitrarily combined without conflict, to obtain new method embodiments or device embodiments.

The above content shows only some implementation modes of the embodiments of this disclosure, but the scope of protection of the embodiments of this disclosure is not limited to this. Those skilled in the art can easily think of changes or replacements within the scope of the technology disclosed in the embodiments of this disclosure, which all shall be covered by the scope of protection of the embodiments of this disclosure. Therefore, the scope of protection of the embodiments of this disclosure should be subject to the scope of protection of the appended claims.

What is claimed is:

1. A leak detection cart, at least comprising a cart body and a fixing clip arranged on the cart body;
wherein the cart body is configured to place a component to be leak-detected;
the fixing clip is configured to fix the cart body and the component to be leak-detected; and
the cart body is provided with a leak detection hole, the leak detection hole being located in a projection region of the component to be leak-detected on the cart body and being configured to implement a leak detection for the component to be leak-detected.

2. The leak detection cart of claim 1, wherein the cart body at least comprises a box body, the box body being provided with a base plate and at least one side plate connected to the base plate; and
wherein the leak detection hole is located in the base plate, the fixing clip is located on at least one side plate, and the box body is configured to place the component to be leak-detected.

3. The leak detection cart of claim 2, wherein the base plate is further provided with a groove located at a contact position of the base plate with the component to be leak-detected; and
wherein the groove is configured to place a sealing element, to achieve a sealing between the base plate and the component to be leak-detected by the sealing element.

4. The leak detection cart of claim 3, wherein the cart body further comprises a connecting support, and the leak detection cart further comprises a brake universal wheel;
an end of the connecting support is fixedly connected to the box body, and the connecting support is configured to support the box body; and
another end of the connecting support is rotatably connected to the brake universal wheel, and the leak detection cart is able to freely move through the brake universal wheel.

5. The leak detection cart of claim 4, further comprising a supporting platform arranged between connecting supports;
wherein the supporting platform is located in a projection region of the base plate, and an area of the supporting platform is less than or equal to an area of the base plate.

6. The leak detection cart of claim 5, wherein the connecting support comprises a connecting rod and an adjusting leg frame; and
the connecting rod is engaged with the adjusting leg frame, the connecting rod and the adjusting leg frame can move relative to each other, and the connecting rod and the adjusting leg frame are configured to adjust a height of the leak detection cart together.

7. The leak detection cart of claim 6, wherein the supporting platform is fixedly or slidably connected to the adjusting leg frame; and
the adjusting leg frame is also configured to adjust a height of the supporting platform.

8. The leak detection cart of claim 1, wherein the leak detection hole is connected to an end of a leak detection pipeline through a flange; and
another end of the leak detection pipeline is connected to a vacuum pump and a leak detector respectively, and the vacuum pump and the leak detector are configured to perform a leak detection on the component to be leak-detected together through the leak detection pipeline and the leak detection hole.

9. The leak detection cart of claim 1, wherein the component to be leak-detected at least comprises a first component and a second component; and
wherein the first component and the second component are respectively two separate parts on a machine.

10. The leak detection cart of claim 9, wherein the first component comprises a chamber dome, and the second component comprises a top injector; and
the chamber dome and the top injector are two separate parts on a film deposition machine.

11. The leak detection cart of claim 3, wherein the sealing element is a sealing ring or a sealing strip.

12. The leak detection cart of claim 6, wherein a plurality of protrusions are provided on one of the adjusting leg frame and the corresponding connecting rod and a plurality of notches are provided in the other one of the adjusting leg frame and the corresponding connecting rod.

13. The leak detection cart of claim 12, wherein the notches and the protrusions are configured to adjust a relative position of the connecting rod to the adjusting leg frame together.

14. The leak detection cart of claim 8, wherein the vacuum pump is a gas capturing pump or a gas transfer pump.

15. The leak detection cart of claim 8, wherein the leak detector is a helium detector, an argon detector, a krypton detector or a xenon detector.

16. A leak detection method at least applied to a leak detection cart, the leak detection cart at least comprising a cart body and a fixing clip arranged on the cart body, wherein the cart body is configured to place a component to be leak-detected; the fixing clip is configured to fix the cart body and the component to be leak-detected; and the cart body is provided with a leak detection hole, the leak detection hole being located in a projection region of the component to be leak-detected on the cart body and being configured to implement a leak detection for the component to be leak-detected; the leak detection method comprising:
performing a pre-leak-detection on the component to be leak-detected by the leak detection cart; and
performing a further leak detection on the component to be leak-detected on a machine when a result of the pre-leak-detection meets a requirement.

17. The method of claim 16, wherein the leak detection cart at least comprises a cart body and a fixing clip arranged on the cart body, and the cart body at least comprises a box body at least provided with a base plate, the base plate being provided with a leak detection hole and a groove; and
wherein said performing the pre-leak-detection on the component to be leak-detected by the leak detection cart comprises:
placing a sealing element in the groove;
hermetically fixing the component to be leak-detected on the leak detection cart by the sealing element and the fixing clip;
connecting the leak detection hole, a vacuum pump and a leak detector by a leak-detection pipeline; and
performing the pre-leak-detection on the component to be leak-detected by the vacuum pump and the leak detector.

18. The method of claim 17, wherein said performing the pre-leak-detection on the component to be leak-detected by the vacuum pump and the leak detector comprises:
vacuumizing a sealed space between the component to be leak-detected and the leak detection cart by the vacuum pump;
spraying a type of gas outside the component to be leak-detected, wherein the leak detector is able to detect the type of gas; and
performing a continuous gas extracting treatment on the sealed space by the leak detector, so as to implement the pre-leak-detection on the component to be leak-detected.

19. The method of claim 18, wherein the component to be leak-detected at least comprises a first component and a second component, the first component and the second component are two separate parts on the machine, and wherein the method, before hermetically fixing the component to be leak-detected on the leak detection cart, further comprises:
fixedly combining the first component and the second component to form a fixedly combined structure.

20. The method of claim 19, wherein said performing the further leak detection on the component to be leak-detected on the machine comprises:
disassembling the fixedly combined structure subjected to the pre-leak detection;
installing the disassembled fixedly combined structure onto the machine; and
performing the further leak detection on the fixedly combined structure on the machine by the leak detector.
